(19) United States
(12) Patent Application Publication
(10) Pub. No.: US 2013/0119458 A1
(43) Pub. Date: May 16, 2013

(54) NOR FLASH MEMORY CELL AND STRUCTURE THEREOF

(71) Applicant: eMemory Technology Inc., Hsinchu (TW)

(72) Inventors: Meng-Yi Wu, Kaohsiung City (TW); Ching-Sung Yang, Hsinchu City (TW)

(73) Assignee: EMEMORY TECHNOLOGY INC., Hsinchu (TW)

(21) Appl. No.: 13/717,725

(22) Filed: Dec. 18, 2012

Related U.S. Application Data
(62) Division of application No. 13/295,102, filed on Nov. 14, 2011.

(51) Int. Cl. H01L 29/792

(52) U.S. Cl. CPC H01L 29/792
USPC 257/326

(57) ABSTRACT

The present invention provides a NOR flash memory cell. The NOR flash memory cell includes a a substrate, an active area, a first gate structure, a second gate structure and at least one third gate structure. The first gate structure covers a first partial region of the active area and is formed by a silicon-rich nitride material. The second gate structure covers a second partial region of the active area. The third gate structure covers a third partial region between a first opening and the first gate structure. The active area has the first opening, the first opening disposed on a first side of the first gate structure and the first side is not neighbor to the second gate structure. The NOR flash memory cell further comprises a first conducting structure for covering the first opening to form a bit line signal receiving terminal.

### CROSS REFERENCE TO RELATED APPLICATION

This application is a divisional of and claims the priority benefit of U.S. patent application Ser. No. 13/295,102 filed on Nov. 14, 2011, now pending. The entirety of the above-mentioned patent application is hereby incorporated by reference herein and made a part of this specification.

### BACKGROUND OF THE INVENTION

1. Field of Invention

The present invention generally relates to a flash memory cell, and more particularly to a NOR flash memory cell.

2. Description of Prior Art

Providing high capacity and long service life non-volatile memory in consumer electronics products is increasingly important nowadays. With the rapid advancement of the flash memory technology, high capacity and long service life non-volatile memory device constructed by flash memory has become the main stream.

### SUMMARY OF THE INVENTION

The present invention provides a NOR flash memory cell and structure with fast programming speed and less power consumption.

The present invention provides a NOR flash memory cell. The NOR flash memory cell comprises a first transistor, a second transistor and at least one third transistor. The first transistor has a control terminal, a first terminal and a second terminal. The control terminal used to receive a word line signal and the first terminal used to receive a bit line signal. Wherein, a gate of the first transistor comprises a silicon-rich nitride layer and an oxide layer, wherein the silicon-rich nitride layer is buried in the oxide layer. The second transistor has a control terminal, a first terminal and a second terminal. The control terminal of the second transistor used to receive a read signal, and the first terminal of the second transistor coupled to the second terminal of the first transistor. The second terminal of the second transistor used to transport a source line signal according to the read signal. The third transistor coupled between the first terminal of the first transistor and the bit line signal. The third transistor has a control terminal, a first terminal and a second terminal. The control terminal of the third transistor receives a midway control signal, the first terminal of the third transistor receives the bit line signal and the second terminal of the third transistor coupled to the first terminal of the first transistor.

The present invention provides a structure of a NOR flash memory cell comprises a substrate, an active area, a first gate structure, a second gate structure and at least one third gate structure. The active area disposed on the substrate. The first gate structure disposed on the active area, and the first gate structure covers a first partial region of the active area. Wherein, the first gate structure is formed by a silicon-rich nitride material. The second gate structure disposed on the active area and the second gate structure covers a second partial region of the active area. The third gate structure disposed on the active area and the third gate structure covers a third partial region between a first opening and the first gate structure. Wherein, the active area has the first opening, the first opening disposed on a first side of the first gate structure and the first side is not neighbor to the second gate structure, the NOR flash memory cell further comprises a first conducting structure for covering the first opening to form a bit line signal receiving terminal.

Accordingly, the NOR flash memory cell having a transistor which provides a gate with a silicon nitride-rich material as a charge storage material. Compared to a transistor with silicon nitride (SiN) gate, the transistor with the silicon nitride-rich material gate provides shallow trapping level, improves FN efficiency and increases trapping center to help charge trap efficiency.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a NOR flash memory cell.

FIG. 2 is a circuit diagram of a flash memory.

FIG. 3 is another circuit diagram of a NOR flash memory cell.

FIG. 4 is another circuit diagram of a flash memory.

FIG. 5 is a structure of a NOR flash memory cell.

FIG. 6 is another structure of a NOR flash memory cell.

### DESCRIPTION OF THE EMBODIMENTS

Reference will now be made in detail to the present preferred embodiment of the invention, examples of which are illustrated in the accompanying drawings. Wherever possible, the same reference numbers are used in the drawings and the description to refer to the same or like parts.

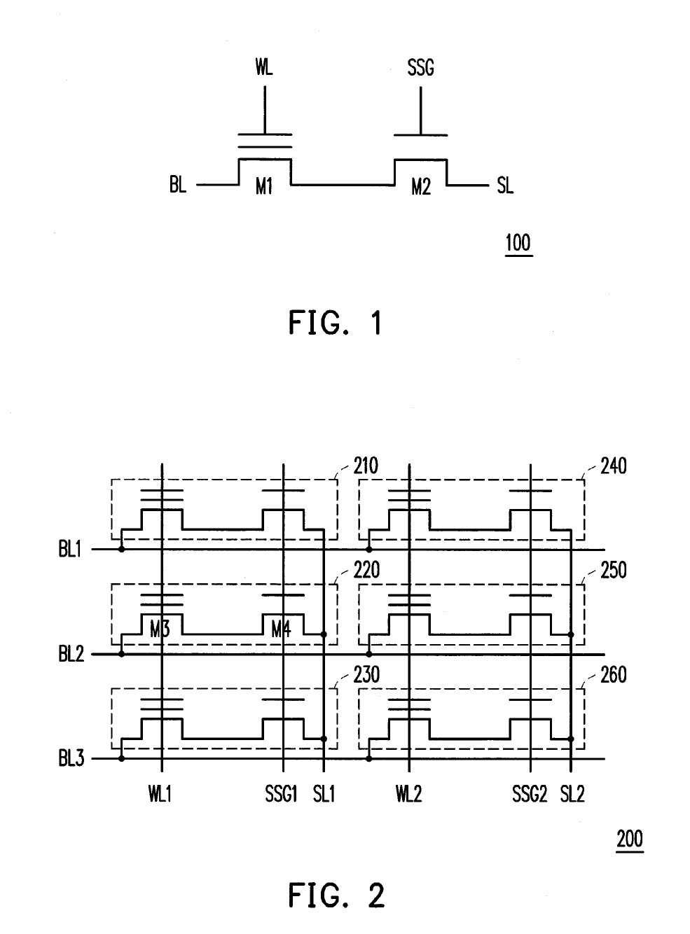

Referring to FIG. 1, FIG. 1 is a circuit diagram of a NOR flash memory cell. The NOR flash memory cell 100 includes a first transistor M1 and a second transistor M2. The first transistor M1 has a control terminal (gate), a first terminal (drain/source) and a second terminal (source/drain). The control terminal of the first transistor M1 is used to receive a word line signal WL and the second terminal of first transistor M1 is coupled to the transistor M2. Wherein, the transistors M1-M2 can be N type transistors or P-type transistors.

The transistor M2 has a control terminal (gate), a first terminal (drain/source) and a second terminal (source/drain). The control terminal of the transistor M2 is used to receive a read signal SSG, the first terminal of the transistor M2 is directly connected to the second terminal of the transistor M1, and the second terminal of the transistor M2 is used to transport a source line signal SL according to the read signal SSG

In this embodiment, the transistor M1 and M2 are all N-type metal oxide semiconductor (NMOS) transistor.

Please notice here, the transistor M1 is adopted for storage function to achieve fast program and erase instead of traditional transistor. That is, the gate dielectric of the transistor M1 is formed by a silicon-rich nitride layer. More specifically, the gate dielectric of the transistor M1 is formed by an oxide layer and the silicon-rich nitride layer, and the silicon-rich nitride layer is buried in the oxide layer (Oxide-SiRN-Oxide structure, wherein the SiRN means silicon-rich nitride layer). Wherein, the silicon-rich nitride layer can be composed of silicon nitride (Si₃N₄) or silicon oxynitride (SixNyOz).

Compared to the traditional transistor with silicon-nitride (SiN) gate, the transistor M1 has shallow trapping levels, and the transistor M1 with the silicon-rich nitride layer increases trapping centers to help charge trap efficiency and FN efficiency. Such as that, stress of tunneling oxide/top oxide of the transistor M1 can be minimized.

In the other hand, material of the gate of the transistor M2 is not limited. The transistor M2 can be the traditional transistor with a silicon gate or a SiN gate. Of course, the transistor M2 can be a transistor with the silicon-rich nitride gate.

Referring to FIG. 2, FIG. 2 is a circuit diagram of a flash memory. The flash memory 200 illustrated in FIG. 2 is formed by a plurality of NOR flash memory cells 210-260. The NOR flash memory cells 210-260 are arranged in an array. The circuit structure of each of the NOR flash memory cells 210-260 is same as the NOR flash memory cell 100. In this embodiment, the NOR flash memory cell 210 and 240 receive the bit line signal BL1, the NOR flash memory cell 220 and 250 receive the bit line signal BL2, and the NOR flash memory cell 230 and 260 receive the bit line signal BL3. The NOR flash memory cell 210-230 receive word line signal WL1 and read signal SSG1, and the NOR flash memory cell 240-260 receive word line signal WL2 and read signal SSG2. Moreover, the source line signals transported by the NOR flash memory cell 210-230 are wired together to be the source line signal SL1. The source line signals transported by the NOR flash memory cell 240-260 are wired together to be the source line signal SL2.

When the flash memory 200 executes a programming operation, a high voltage (14V for example) is provided to one of the world line signals WL1-WL2, and a low voltage (0V for example) is provided to one of the bit line signals BL1-BL3. For example, if the NOR memory cell 220 is selected to be programmed. The voltage level of the word line signal WL1 raise to the high voltage 14V and the voltage level of the bit line signal BL2 be set at the low voltage 0V, and the transistor M3 in the NOR memory cell 220 is programmed according to the voltage drop (14-0=14V) between the gate and drain (or source) of the transistor M3 which enables Fowler-Nordheim tunneling mechanism. At the same time, the voltage level of the word line single WL2 is kept at the low voltage 0V, and the voltage level of the bit line signals BL1 and BL3 are set at 5V for example. Therefore, the NOR memory cells 210 and 230-260 are not programmed for the voltage drop between the word line signal and the bit line signal thereof is not large enough. Besides, the voltage level of the read signals SSG1 and SSG2 for executing the programming operation are kept at 0V.

When the flash memory 200 executes an erase operation, the substrates of the transistors receiving the word line signal WL1 and WL2 in flash memory 200 are pulled to the high voltage 14V. At the same time, the word line signal WL1 and WL2 are set to 0V and the NOR flash memory cell 210-260 are erased according to the voltage drop (0-14=−14V) between the gate and the substrate of the transistors receiving the word line signal WL1 or WL2 which enables Fowler-Nordheim tunneling mechanism.

When the flash memory 200 executes a data read operation, the low voltage 0V is provided to one of the world line signals WL1-WL2, a read voltage (3V for example) is provided to one of the read signal SSG1 and SSG2, and a read corresponding voltage (1V for example) is provided to one of the bit line signals BL1-BL3. For example, if the NOR memory cell 220 is selected to be read, the voltage level of the world line signal WL1 is set to low voltage 0V, the read signal SSG1 is set to the read voltage 3V, and the bit line signal BL1 is set to the read corresponding voltage 1 V. The data stored in the transistor M3 of the NOR memory cell 220 is transported to the bit line signal BL1 through the transistor M4 which is turned on according to the read signal SSG1. At the same time, the world line signal WL2 and the read signal SSG2 are set to 0V and the bit line signals BL1 and BL3 are set to 0V, too. The data stored in the NOR memory cells 210 and 230-260 are not transported out.

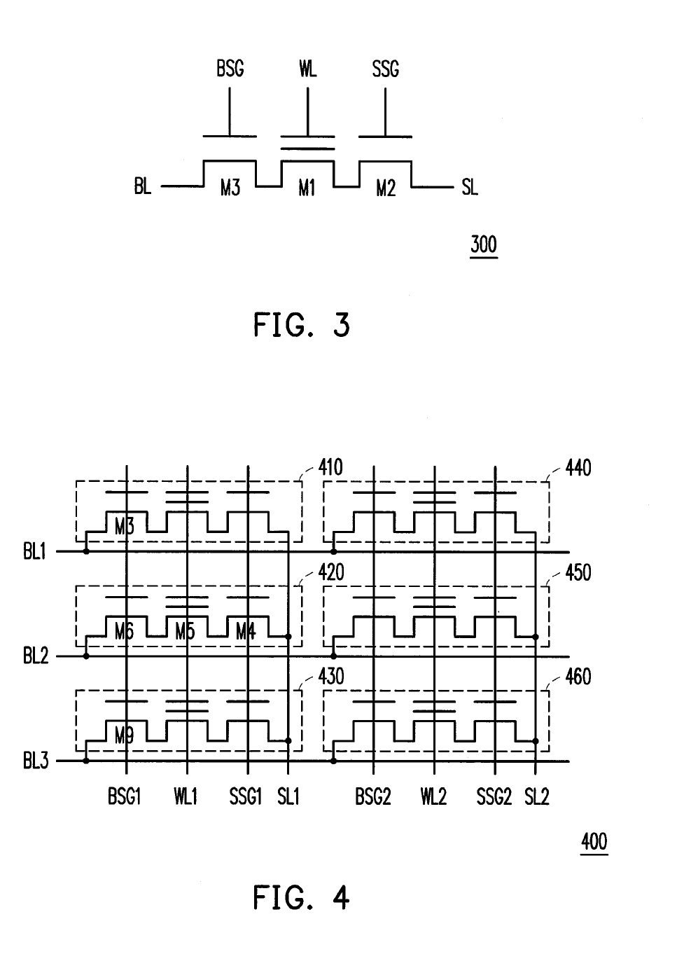

Referring to FIG. 3, FIG. 3 is another circuit diagram of a NOR flash memory cell. In this embodiment, the NOR flash memory cell 300 includes three transistors M1-M3. Each of the transistors M1-M3 has a control terminal (gate), a first terminal (drain/source) and a second terminal (source/drain). The connection configuration of the transistor M1 and M2 are same to the illustration in FIG. 1. The transistor M3 is coupled between the first terminal of the transistor M1 and the bit line signal BL. That is, the transistor M1 receives the bit line signal BL through the transistor M3. Please notice here, the number of the transistor M1 can be 1 or larger than 1. If the NOR flash memory cell includes a plurality of transistors M1, the transistors M1 are coupled in serial between the bit line signal BL and the transistor M2. The gates of the transistors M3 are use to receive the midway control signal BSG commonly. Wherein, the transistors M1-M3 can be N type transistors or P-type transistors.

Referring to FIG. 4, FIG. 4 is another circuit diagram of a flash memory. The flash memory 400 includes a plurality of NOR flash memory cells 410-460. The NOR flash memory cells 410-460 are arranged in an array. The circuit structure of each of the NOR flash memory cells 410-460 is same as the NOR flash memory cell 300.

When the flash memory 400 executes a programming operation, a high voltage (14V for example) is provided to one of the world line signals WL1-WL2, a voltage (2.5V for example) is provided to one of the midway control signal BSG1 and BSG2, and a low voltage (0V for example) is provided to one of the bit line signals BL1-BL3. For example, if the NOR memory cell 420 is selected to be programmed. The voltage level of the word line signal WL1 raise to the high voltage 14′V, the voltage level of the midway control signal BSG1 is set to 2.5V, and the voltage level of the bit line signal BL2 be set at the low voltage 0V, and the transistor M4 in the NOR memory cell 420 is programmed according to the voltage drop between the gate and channel of the transistor M5, which enables Fowler-Nordheim tunneling mechanism. At the same time, the voltage level of the word line single WL2 is kept at the low voltage 0V, the voltage level of the midway control signal is set to 0V, and the voltage level of the bit line signals BL1 and BL3 are set at 2.5V for example. Therefore, the NOR memory cells 410 and 430-460 are not programmed for the voltage drop between the word line signal and the bit line signal thereof is not large enough. Please note here, the voltage level of bit line signals BL1-BL2 received by the transistors M3, M6 and M9 in the NOR flash memory cells 410, 420 and 430 respectively is swing between 2.5V and 0V. That is, a voltage level with 5V is no more needed in this embodiment, and the power consumption of the flash memory 400 can be reduced. Besides, the voltage level of the read signals SSG1 and SSG2 are kept at 0V.

Please notice here, for the voltage 2.5V are provided to the midway control signals BSG1 and bit line signals BL1 and BL2, the NOR flash memory cells 410 and 430 are inhibited when the voltage level of the word line signal WL1 raise to the high voltage 14V. That is, the NOR flash memory cells are inhibited from being programmed.

When the flash memory 400 executes an erase operation, the substrates of the transistor receiving the word line signal WL1 and WL2 in flash memory 400 are pulled to the high voltage 14V. At the same time, the word line signal WL1 and WL2 are set to 0V, and the NOR flash memory cell 410-460 are erased according to the voltage drop (0-14=−14V) between the gate and the substrate of the transistors receiving the word line signal WL1 or WL2 which enables Fowler-Nordheim tunneling mechanism. When the flash memory 400 executes a data read operation, the low voltage 0V is provided to the world line signals WL1-WL2, a read voltage (3V for example) is provided to one of the read signal SSG1 and SSG2, a voltage (2.5V for example) is provided to one of the midway control signal BSG1 and BSG2, and a read corresponding voltage (1V for example) is provided to one of the bit line signals BL1-BL3. For example, if the NOR memory cell 420 is selected to be read, the voltage level of the world line signal WL1 is set to low voltage 0V, the read signal SSG1 is set to the read voltage 3V, the midway control signal BSG1 is set to 2.5V, and the bit line signal BL2 is set to the read corresponding voltage 1V. The data stored in the transistor M5 of the NOR memory cell 420 is transported to the source line signal SL1 through the transistor M4 which is turned on according to the read signal SSG1. At the same time, the world line signal WL2, the midway control signal BSG2, and the read signal SSG2 are set to 0V and the bit line signals BL1 and BL3 are set to 0V, too. The data stored in the NOR memory cells 410 and 430-460 are not transported out.

When the flash memory 400 executes an erase operation, the substrates of the transistor receiving the word line signal WL1 and WL2 in flash memory 400 are pulled to the high voltage 14V. At the same time, the word line signal WL1 and WL2 are set to 0V, and the NOR flash memory cell 410-460 are erased according to the voltage drop (0-14=−14V) between the gate and the substrate of the transistors receiving the word line signal WL1 or WL2 which enables Fowler-Nordheim tunneling mechanism. When the flash memory 400 executes a data read operation, the low voltage 0V is provided to the world line signals WL1-WL2, a read voltage (3V for example) is provided to one of the read signal SSG1 and SSG2, a voltage (2.5V for example) is provided to one of the midway control signal BSG1 and BSG2, and a read corresponding voltage (1V for example) is provided to one of the bit line signals BL1-BL3. For example, if the NOR memory cell 420 is selected to be read, the voltage level of the world line signal WL1 is set to low voltage 0V, the read signal SSG1 is set to the read voltage 3V, the midway control signal BSG1 is set to 2.5V, and the bit line signal BL2 is set to the read corresponding voltage 1V. The data stored in the transistor M5 of the NOR memory cell 420 is transported to the source line signal SL1 through the transistor M4 which is turned on according to the read signal SSG1. At the same time, the world line signal WL2, the midway control signal BSG2, and the read signal SSG2 are set to 0V and the bit line signals BL1 and BL3 are set to 0V, too. The data stored in the NOR memory cells 410 and 430-460 are not read out.

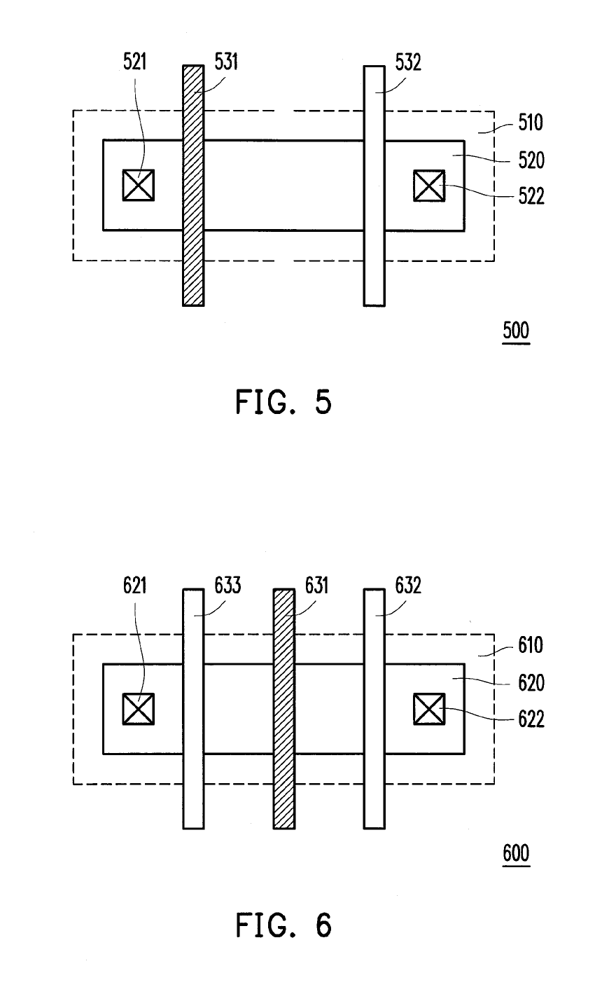

Referring to FIG. 5, FIG. 5 is a structure of a NOR flash memory cell. The NOR flash memory cell 500 includes a substrate 510, a active area 520, gate structures 531 and 532, a bit line signal receiving terminal 521 and a source line signal transporting terminal 522. The active area 520 is disposed on the substrate 510, and the substrate 510 can be a P-type substrate of a wafer or a P-type well in a N-type substrate. The first gate structure disposed on the active area 520 and the gate structure 531 covers a first partial region of the active area 520, wherein, a silicon-rich nitride material is included in the gate structure 531. The gate structure disposed on the active area 520 and the gate structure 532 covers a second partial region of the active area 520.

In this embodiment, the active area 520 has a first opening, the first opening disposed on a first side of the gate structure 531 and the first side is not neighbor to the structure 532. The NOR flash memory cell 500 further includes a first conducting structure for covering the first opening to form a bit line signal receiving terminal 521. In the other way, the active area 520 further has a second opening, the second opening disposed on a second side of the gate structure 532 and the second side is not neighbor to the gate structure 531. The NOR flash memory cell 500 further includes a second conducting structure for covering the second opening to form a source line signal transporting terminal 522.

In this embodiment, the gate structure 532 can be formed by a silicon-rich nitride material and a poly material. Wherein the silicon-rich nitride material can be silicon nitride (Si₃N₄) or silicon oxynitride (SixNyOz).

Referring to FIG. 6, FIG. 6 is another structure of a NOR flash memory cell. The NOR flash memory cell 600 includes a substrate 610, a active area 620, gate structures 631, 632 and 633, a bit line signal receiving terminal 621 and a source line signal transporting terminal 622. Compared to the embodiment illustrated by FIG. 5, the NOR flash memory cell 600 further including a gate structure 633. The gate structure 633 disposed on the active area 620 and the gate structure 633 covers a third partial region between the first opening and the gate structure 631.

In this embodiment, the gate structure 633 can be formed by a silicon-rich nitride material or a poly material.

In summary, in the present invention, the NOR flash memory cell has a transistor which provides a gate with a silicon nitride-rich material as a charge storage material. That is, compared to a transistor with silicon nitride (SiN) gate, the FN efficiency is improved by using the transistor with the silicon nitride-rich material gate. The performance of the system the NOR flash memory cell belonged to is improved correspondingly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

what is claimed is:

1. A structure of a NOR flash memory cell, comprising:
a substrate;
an active area, disposed on the substrate;
a first gate structure, disposed on the active area and the first gate structure covers a first partial region of the active area, wherein, the first gate structure is formed by a silicon-rich nitride material; and
a second gate structure, disposed on the active area and the second gate structure covers a second partial region of the active area; and
at least one third gate structure, disposed on the active area and the third gate structure covers a third partial region between a first opening and the first gate structure,
wherein, the active area has the first opening, the first opening disposed on a first side of the first gate structure and the first side is not neighbor to the second gate structure, the NOR flash memory cell further comprises a first conducting structure for covering the first opening to form a bit line signal receiving terminal.

2. The structure of the NOR flash memory cell according to claim 1, wherein the active area further has a second opening, the second opening disposed on a second side of the second gate structure and the second side is not neighbor to the first gate structure, the NOR flash memory cell further comprises a second conducting structure for covering the second opening to form a source line signal transporting terminal.

3. The structure of the NOR flash memory cell according to claim 1, wherein the third gate structure is formed by a silicon-rich nitride material or a poly material.

4. The structure of the NOR flash memory cell according to claim 1, wherein the second gate structure is formed by a silicon-rich nitride material or a poly material.

5. The structure of the NOR flash memory cell according to claim 1, wherein the first gate structure is used to receive a word line signal, and the second gate structure is used to receive a read signal.

6. The structure of the NOR flash memory cell according to claim 1, wherein the substrate is P-Type substrate.

7. The structure of the NOR flash memory cell according to claim 1, wherein the silicon-rich nitride material is composed of silicon nitride (Si₃N₄).

8. The structure of the NOR flash memory cell according to claim 1, wherein the silicon-rich nitride material is composed of silicon oxynitride (SixNyOz).
